(19) United States
(12) Patent Application Publication
(10) Pub. No.: US 2025/0191922 A1
(43) Pub. Date: Jun. 12, 2025

(54) METHOD OF FORMING ELECTRODE WITH MULTI-DIELECTRIC LAYERS

(71) Applicant: MIKRO MESA TECHNOLOGY CO., LTD., APIA (WS)

(72) Inventors: Li-Yi CHEN, Tainan City (TW); Chieh-Ting CHEN, Hsinchu City (TW)

(21) Appl. No.: 18/530,212

(22) Filed: Dec. 6, 2023

(51) Int. Cl. H01L 21/28; H01L 21/311

(52) U.S. Cl. CPC H01L 21/28079; H01L 21/28141; H01L 21/31111; H01L 21/31144

(57) ABSTRACT

A method of forming an electrode with multi-dielectric layers includes: forming a metal pattern on a substrate, in which the metal pattern includes a first metal film on the substrate and a second metal film on a top surface of the first metal film, and the first and second metal films have different metal compositions; and anodizing the metal pattern in a liquid electrolyte to form a covering anodized portion which covers an unanodized portion, in which the covering anodized portion includes a sidewall oxide dielectric structure and a top oxide dielectric structure, the sidewall oxide dielectric structure is in contact with a side surface of the unanodized portion, the top oxide dielectric structure is in contact with top surfaces of the unanodized portion and the sidewall oxide dielectric structure, and the sidewall and top oxide dielectric structures have different effective permittivities.

### BACKGROUND

### Field of Invention

The present disclosure relates to a method of forming an electrode with multi-dielectric layers.

### Description of Related Art

The statements in this section merely provide background information related to the present disclosure and do not necessarily constitute prior art.

Traditional display manufacturing is a standardized process set. In recent years, there are more and more new types of displays such as a micro light-emitting diode display, a mini light-emitting diode display, and a quantum dot light-emitting diode display . . . , etc., which are promising to dominate the future display market, and thus new display manufacturing processes are waiting to be set up. There are many steps contained in a manufacturing process set in order to produce one display, and reducing one of the steps thereof can reduce the cost and enhance the efficiency.

### SUMMARY

According to some embodiments of the present disclosure, a method of forming an electrode with multi-dielectric layers includes: forming a metal pattern on a substrate, in which the metal pattern includes a first metal film on the substrate and a second metal film on a top surface of the first metal film, and a metal composition of the first metal film and a metal composition of the second metal film are different; and anodizing the metal pattern in a liquid electrolyte to form a covering anodized portion which covers an unanodized portion, in which the covering anodized portion includes a sidewall oxide dielectric structure and a top oxide dielectric structure, the sidewall oxide dielectric structure is in contact with a side surface of the unanodized portion, the top oxide dielectric structure is in contact with a top surface of the unanodized portion and a top surface of the sidewall oxide dielectric structure, and the sidewall oxide dielectric structure and the top oxide dielectric structure have different effective permittivities.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1A to 1E are schematic cross-sectional views of intermediate stages of a method of manufacturing a structure having multi-dielectric layers according to some embodiments of the present disclosure;

FIG. 2 is a schematic cross-sectional view of a structure having multi-dielectric layers according to some embodiments of the present disclosure;

FIG. 3 is a schematic cross-sectional view of a structure having multi-dielectric layers according to some embodiments of the present disclosure;

FIG. 4 is a schematic diagram illustrating an anodization process according to some embodiments of the present disclosure;

FIGS. 5A to 5E are schematic cross-sectional views of intermediate stages of a method of manufacturing a structure having multi-dielectric layers according to some embodiments of the present disclosure;

FIG. 5F is a schematic top view of the structure in FIG. 5E according to some embodiments of the present disclosure;

FIG. 6A is a schematic cross-sectional view of a structure having multi-dielectric layers according to some embodiments of the present disclosure;

FIG. 6B is a schematic top view of the structure of FIG. 6A according to some embodiments of the present disclosure;

FIG. 7 is a schematic cross-sectional view of a structure having multi-dielectric layers according to some embodiments of the present disclosure;

FIG. 8 is a schematic cross-sectional view of a structure having multi-dielectric layers according to some embodiments of the present disclosure;

FIG. 9A is a schematic cross-sectional view of an intermediate stage of a method of manufacturing a structure having multi-dielectric layers according to some embodiments of the present disclosure;

FIG. 9B is a schematic cross-sectional view of an intermediate stage of a method of manufacturing a structure having multi-dielectric layers according to some embodiments of the present disclosure;

FIG. 10 is a schematic top view of a structure having multi-dielectric layers according to some embodiments of the present disclosure;

FIG. 11 is a schematic cross-sectional view of a structure having multi-dielectric layers according to some embodiments of the present disclosure;

FIG. 12 is a schematic cross-sectional view of a structure having multi-dielectric layers according to some embodiments of the present disclosure; and

FIG. 13 is a schematic cross-sectional view of a structure having multi-dielectric layers according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “according to some embodiments” or the like in various places throughout this specification are not necessarily referring to the same embodiment of the disclosure. Furthermore, the particular features, structures, configurations, or characteristics may be combined in any suitable manner in one or more embodiments.

The terms “micro” device, “micro” p-n diode or “micro” LED as used herein may refer to the descriptive size of certain devices or structures according to embodiments of the present disclosure. As used herein, the terms “micro” devices or structures may be meant to refer to the scale of 1 to 100 μm. However, it is to be appreciated that embodiments of the present disclosure are not necessarily so limited, and that certain aspects of the embodiments may be applicable to larger, and possibly smaller size scales.

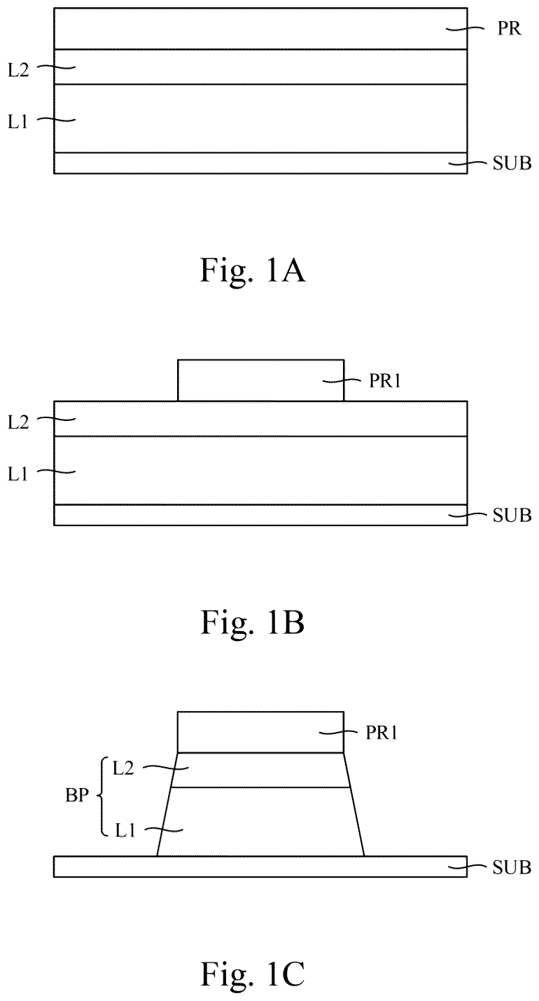

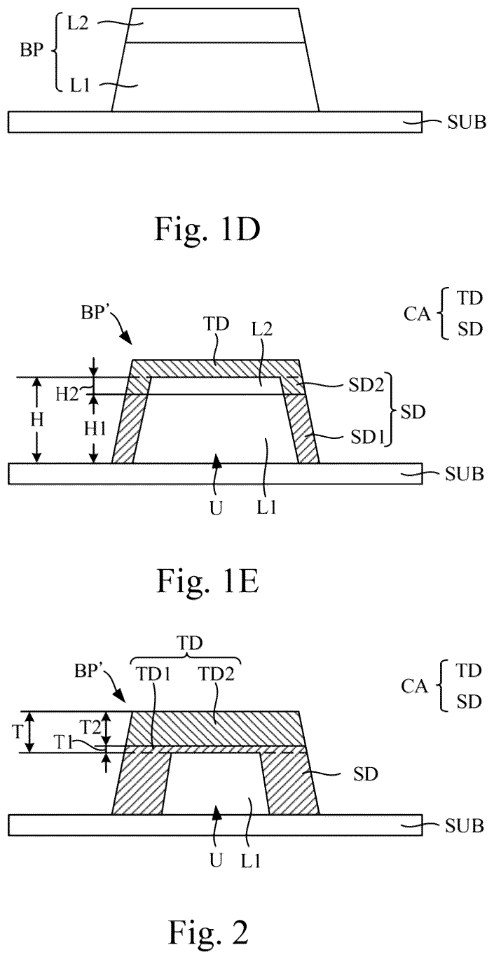

Reference is made to FIG. 1A. FIG. 1A is a schematic cross-sectional view of an intermediate stage of a method of manufacturing a structure having multi-dielectric layers according to some embodiments of the present disclosure. As shown in FIG. 1A, a first metal film L1 is deposited on a substrate SUB, a second metal film L2 is deposited on the first metal film L1, and a photoresist PR is formed on the second metal film L2.

In some embodiments, the second metal film L2 contains aluminum, but the present disclosure is not limited in this regard.

In some embodiments, the second metal film L2 is an aluminum alloy containing silicon, but the present disclosure is not limited in this regard.

In some embodiments, the second metal film L2 is an alloy containing rare earth metal, but the present disclosure is not limited in this regard.

In some embodiments, the second metal film is an alloy containing alkaline earth metal, but the present disclosure is not limited in this regard.

In some embodiments, a material of the second metal film includes at least one of hafnium, tantalum, zirconium, titanium, and tungsten, but the present disclosure is not limited in this regard.

In some embodiments, a metal composition of the first metal film L1 and a metal composition of the second metal film L2 are different.

Reference is made to FIG. 1B. FIG. 1B is a schematic cross-sectional view of an intermediate stage of a method of manufacturing a structure having multi-dielectric layers according to some embodiments of the present disclosure. The intermediate stage shown in FIG. 1A may be sequentially followed by the intermediate stage shown in FIG. 1B. As shown in FIG. 1B, the photoresist PR is exposed and developed to be a patterned photoresist PR1.

Reference is made to FIG. 1C. FIG. 1C is a schematic cross-sectional view of an intermediate stage of a method of manufacturing an electrode structure according to some embodiments of the present disclosure. The intermediate stage shown in FIG. 1B may be sequentially followed by the intermediate stage shown in FIG. 1C. As shown in FIG. 1C, an etching process is performed to the first metal film L1 and the second metal film L2 through the patterned photoresist PR1 to form a bottom metal pattern BP. In some embodiments, the etching process is a photo engraving process (PEP), but the present disclosure is not limited in this regard.

Reference is made to FIG. 1D. FIG. 1D is a schematic cross-sectional view of an intermediate stage of a method of manufacturing an electrode structure according to some embodiments of the present disclosure. The intermediate stage shown in FIG. 1C may be sequentially followed by the intermediate stage shown in FIG. 1D. As shown in FIG. 1D, the patterned photoresist PR1 is removed after the etching process is performed.

Reference is made to FIG. 1E. FIG. 1E is a schematic cross-sectional view of an intermediate stage of a method of manufacturing an electrode structure according to some embodiments of the present disclosure. The intermediate stage shown in FIG. 1D may be sequentially followed by the intermediate stage shown in FIG. 1E. As shown in FIG. 1E, the bottom metal pattern BP is anodized in a liquid electrolyte. Specifically, the bottom metal pattern BP is anodized from the outer surface thereof, such that the anodized bottom metal pattern BP′ includes a covering anodized portion CA and an unanodized portion U covered by the covering anodized portion CA. The covering anodized portion CA includes a sidewall oxide dielectric structure SD and a top oxide dielectric structure TD. The sidewall oxide dielectric structure SD is in contact with a side surface of the unanodized portion U. The top oxide dielectric structure TD is in contact with a top surface of the unanodized portion U and a top surface of the sidewall oxide dielectric structure SD. In some embodiments, the sidewall oxide dielectric structure SD may be defined by the anodized part of the anodized bottom metal pattern BP′ below the top surface of the unanodized portion U, and the top oxide dielectric structure TD may be defined by the anodized part of the anodized bottom metal pattern BP′ above the top surface of the unanodized portion U.

In some embodiments, the unanodized portion U has an atomic ratio of aluminum greater than 50%. In this way, the electrical conductivity of an entirety of the unanodized portion U can be increased.

In the present embodiment, as shown in FIG. 1E, both of the first metal film L1 and the second metal film L2 are partially anodized. Specifically, the sidewall oxide dielectric structure SD includes a first metal oxide segment SD1 and a second metal oxide segment SD2 connected to each other. The first metal oxide segment SD1 is the anodized part of the first metal film L1, and the second metal oxide segment SD2 is the anodized part of the second metal film L2. The first metal oxide segment SD1 is in contact with a side surface of the unanodized part of the first metal film L1. The second metal oxide segment SD2 is in contact with a side surface of the unanodized part of the second metal film L2. In other words, the unanodized portion U is a multilayer structure formed by the unanodized part of the first metal film L1 and the unanodized part of the second metal film L2. The top oxide dielectric structure TD only has a single metal oxide layer and is further connected to the second metal oxide segment SD2. It can be seen that a sum of a segment number of the metal oxide segments of the sidewall oxide dielectric structure SD and a layer number of the metal oxide layer of the top oxide dielectric structure TD is equal to three.

In some other embodiments, the sum of the segment number of the metal oxide segment(s) of the sidewall oxide dielectric structure SD and a layer number of the metal oxide layer(s) of the top oxide dielectric structure TD may be greater than three.

In some embodiments, the sidewall oxide dielectric structure SD has a first effective permittivity, and the top oxide dielectric structure TD has a second effective permittivity. Since the top oxide dielectric structure TD only has a single metal oxide layer, the second effective permittivity is just the permittivity of the top oxide dielectric structure TD. In some embodiments where the sidewall oxide dielectric structure SD includes a plurality of metal oxide segments (i.e., the first metal oxide segment SD1 and the second metal oxide segment SD2), the first effective permittivity of the sidewall oxide dielectric structure SD may be obtained by using the following formula (1).

$${ϵ}_{SD} = \frac{{ϵ}_{SD 1} \times H 1 + {ϵ}_{SD 2} \times H 2}{H} \qquad ( 1 )$$

In the formula (1), ϵ_{SD} represents the first effective permittivity of the sidewall oxide dielectric structure SD, ϵ_{SD1} represents the permittivity of the first metal oxide segment SD1, ϵ_{SD2} represents the permittivity of second metal oxide segment SD2, H1 represents the height of the first metal oxide segment SD1 relative to the substrate SUB, H2 represents the height of the second metal oxide segment SD2 relative to the substrate SUB, and H represents the height of an entirety of the sidewall oxide dielectric structure SD.

In some embodiments where the sidewall oxide dielectric structure SD includes more than two metal oxide segments, the first effective permittivity of the sidewall oxide dielectric structure SD may be obtained by using the following formula (2).

$${ϵ}_{SD} = \frac{{ϵ}_{{SD}_{1}} \times H 1 + {ϵ}_{{SD}_{2}} \times H 2 + … + {ϵ}_{SDm}}{H} \qquad ( 2 )$$

In the formula (2), m is an integer greater than two, ϵSDm represents the permittivity of the m-th metal oxide segment of the sidewall oxide dielectric structure SD, and Hm represents the height of the m-th metal oxide segment relative to the substrate SUB.

In some embodiments, the permittivities ϵSD1 and ϵSD2 and the second effective permittivity of the top oxide dielectric structure TD may be measured by using a frequency such as 1 KHz, but the present disclosure is not limited in this regard.

In some embodiments, the second effective permittivity of the top oxide dielectric structure TD is smaller than the first effective permittivity of the sidewall oxide dielectric structure SD. In some embodiments, the top oxide dielectric structure TD contains silicon oxide, such that the first effective permittivity is greater than the second effective permittivity. In addition, since the top oxide dielectric structure TD contains silicon oxide, the top oxide dielectric structure TD covering the unanodized portion U can be stronger and more stable.

In some embodiments, the second effective permittivity of the top oxide dielectric structure TD is greater than the first effective permittivity of the sidewall oxide dielectric structure SD.

Reference is made to FIG. 2. FIG. 2 is a schematic cross-sectional view of a structure having multi-dielectric layers according to some embodiments of the present disclosure. As shown in FIG. 2, the first metal film L1 is partially anodized, and the second metal film L2 is entirely anodized. Specifically, the top oxide dielectric structure includes a first metal oxide layer TD1 and a second metal oxide layer TD2 connected to each other. The first metal oxide layer TD1 is the anodized part of the first metal film L1, and the second metal oxide layer TD2 is the anodized part of the second metal film L2. The first metal oxide layer TD1 is in contact with a top surface of the unanodized part of the first metal film L1. The sidewall oxide dielectric structure SD only has a single metal oxide segment, and the first metal oxide layer TD1 is further connected to the sidewall oxide dielectric structure SD. It can be seen that a sum of a segment number of the metal oxide segment of the sidewall oxide dielectric structure SD and a layer number of the metal oxide layers of the top oxide dielectric structure TD is equal to three.

In some embodiments, the sidewall oxide dielectric structure SD has a first effective permittivity, and the top oxide dielectric structure TD has a second effective permittivity. Since the sidewall oxide dielectric structure SD only has a single metal oxide segment, the first effective permittivity is just the permittivity of the sidewall oxide dielectric structure SD. In some embodiments where the top oxide dielectric structure TD includes a plurality of metal oxide layers (i.e., the first metal oxide layer TD1 and the second metal oxide layer TD2), the second effective permittivity of the top oxide dielectric structure TD may be obtained by using the following formula (3).

$$\frac{T}{{ϵ}_{TD}} = \frac{T 1}{{ϵ}_{{TD}_{1}}} + \frac{T 2}{{ϵ}_{{TD}_{2}}} \qquad ( 3 )$$

In the formula (3), ETD represents the second effective permittivity of the top oxide dielectric structure TD, ETD1 represents the permittivity of the first metal oxide layer TD1, ETD2 represents the permittivity of second metal oxide layer TD2, T1 represents the thickness of the first metal oxide layer TD1, T2 represents the thickness of the second metal oxide layer TD2, and T represents the thickness of an entirety of the top oxide dielectric structure TD.

In some embodiments where the top oxide dielectric structure TD includes more than two metal oxide layers, the second effective permittivity of the top oxide dielectric structure TD may be obtained by using the following formula (4).

$$\frac{T}{{ϵ}_{TD}} = \frac{T 1}{{ϵ}_{{TD}_{1}}} + \frac{T 2}{{ϵ}_{{TD}_{2}}} + … + \frac{Tn}{{ϵ}_{TDn}} \qquad ( 4 )$$

In the formula (4), n is an integer greater than two, ϵ_{TDn} represents the permittivity of the n-th metal oxide layer of the top oxide dielectric structure TD, and Tn represents the thickness of the n-th metal oxide layer.

In some embodiments, the permittivities ETD1 and ETD2 and the first effective permittivity of the sidewall oxide dielectric structure SD may be measured by using a frequency such as 1 KHz, but the present disclosure is not limited in this regard.

It should be pointed out that the formula (2) for calculating the second effective permittivity is obtained from the formula for calculating the capacitance of series connection of parallel plate capacitors. The formula for calculating the capacitance is C=ϵ×A/d, where C is the value of the capacitance, A is the area of each plate, d is the distance between the plates, and e is the permittivity of the material between the plates of the parallel capacitor.

In some embodiments, the layer number of the metal oxide layers of the top oxide dielectric structure TD is equal to two, such as the structure shown in FIG. 1E and the structure shown in FIG. 2, but the present disclosure is not limited in this regard.

In some other embodiments, the layer number of the metal oxide layers of the top oxide dielectric structure TD may be greater than two. To manufacture the structure, an additional metal layer may be deposited on the second metal film L2 after the intermediate stage of FIG. 1B and before the intermediate stage of FIG. 1C.

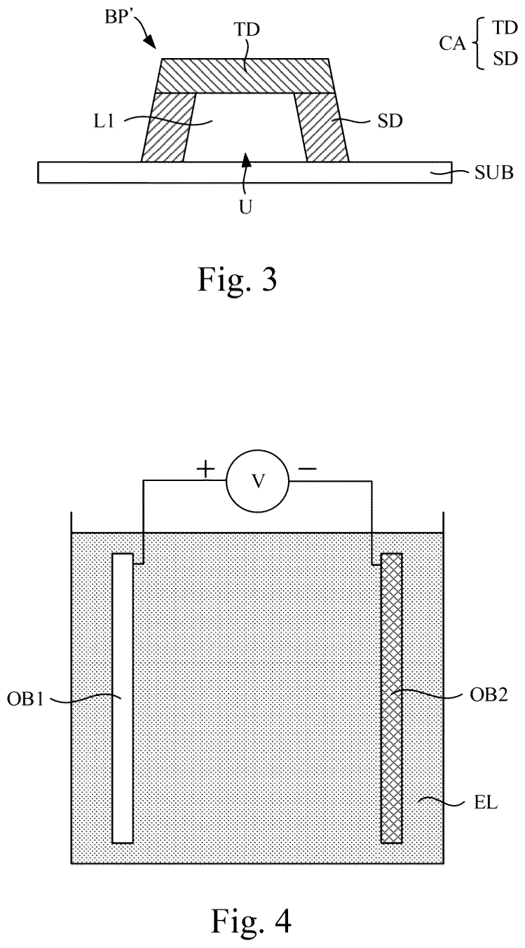

Reference is made to FIG. 3. FIG. 3 is a schematic cross-sectional view of a structure having multi-dielectric layers according to some embodiments of the present disclosure. As shown in FIG. 3, the first metal film L1 is partially anodized, and the second metal film L2 is entirely anodized. Specifically, the sidewall oxide dielectric structure SD only has a single metal oxide segment, and the top oxide dielectric structure TD only has a single metal oxide layer. The sidewall oxide dielectric structure SD is the anodized part of the first metal film L1. The top oxide dielectric structure TD is the anodized part of the second metal film L2. It can be seen that a sum of a segment number of the metal oxide segment of the sidewall oxide dielectric structure SD and a layer number of the metal oxide layer of the top oxide dielectric structure TD is equal to two.

In some embodiments, the sidewall oxide dielectric structure SD has a first effective permittivity, and the top oxide dielectric structure TD has a second effective permittivity. Since the sidewall oxide dielectric structure SD only has a single metal oxide segment, the first effective permittivity is just the permittivity of the sidewall oxide dielectric structure SD. Since the top oxide dielectric structure TD only has a single metal oxide layer, the second effective permittivity is just the permittivity of the top oxide dielectric structure TD.

Reference is made to FIG. 4 in advance. FIG. 4 is a schematic diagram illustrating an anodization process according to some embodiments of the present disclosure. As shown in FIG. 4, a liquid electrolyte EL is put in a container, an object OB1 to be anodized serves as an anode of a power source (e.g., a DC power), and an object OB2 having corrosion-resistant materials serves as a cathode of the power source. The object OB1 may be the structure as shown in FIG. 1D or a semi-finished product of a TFT (thin-film transistor) substrate. The object OB2 may include platinum or graphite.

In some embodiments, the bottom metal pattern BP is anodized by using a liquid electrolyte (e.g., the liquid electrolyte EL in FIG. 4) with a pH value between pH5 and pH8. It should be pointed out that if the pH value is smaller than pH5 or greater than pH8, there will be more pores in the covering anodized portion CA of the anodized bottom metal pattern BP′.

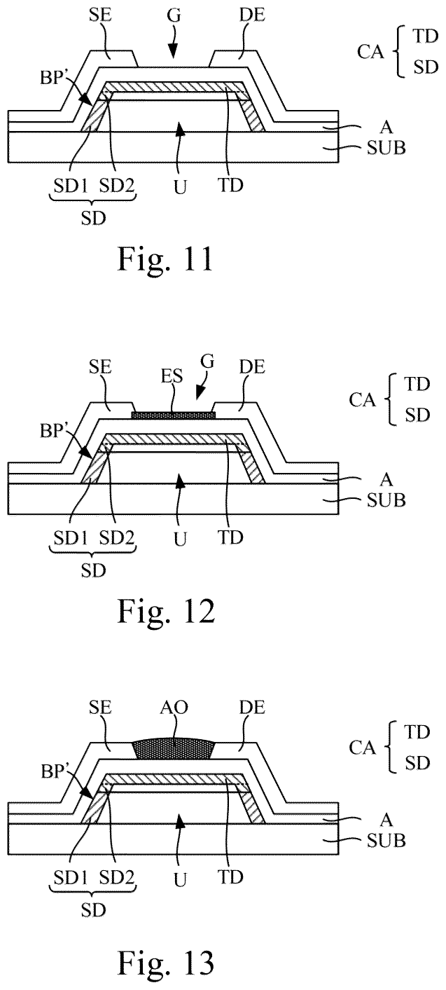

In some embodiments, the bottom metal pattern BP is anodized by using a liquid electrolyte (e.g., the liquid electrolyte EL in FIG. 4) containing a content of water less than 20 wt %. In this way, the Hydrogen content in the covering anodized portion CA of the anodized bottom metal pattern BP′ can be small. The Hydrogen content may reduce the breakdown voltage of the gate insulator. Hydrogen sometimes affects the oxide semiconductor layer A to be manufactured in FIGS. 11-13 and reduces its stability.

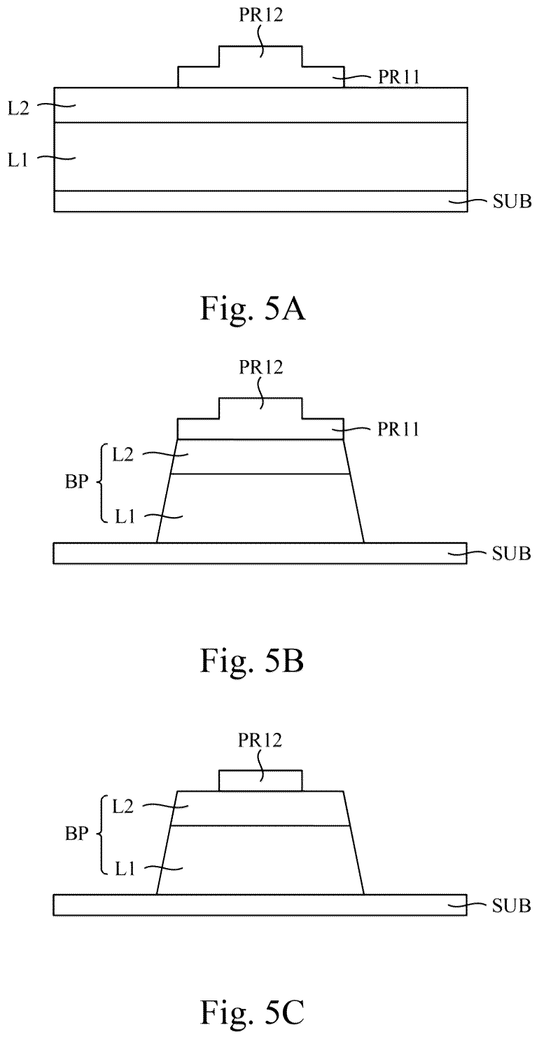

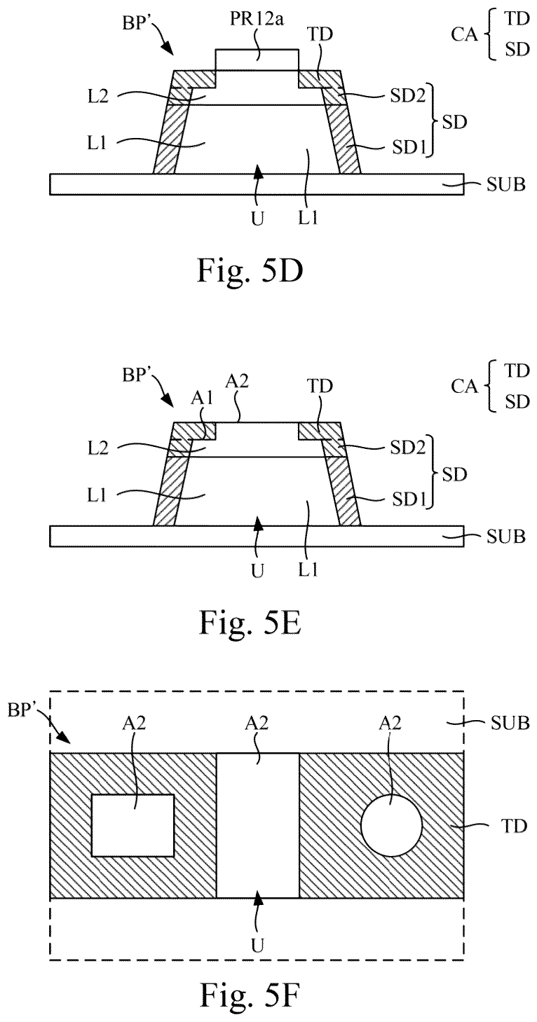

In some embodiments, the intermediate stage shown in FIG. 1A may be sequentially followed by the intermediate stage shown in FIG. 5A. FIG. 5A is a schematic cross-sectional view of an intermediate stage of a method of manufacturing an electrode structure according to some embodiments of the present disclosure. A material of the photoresist PR is positive tone photoresist. After the intermediate stage of FIG. 1A and before the intermediate stage of FIG. 5A, a first region of the photoresist PR is exposed with a first exposure dose of light. Second regions of the photoresist PR are exposed with a second exposure dose of light which is smaller than the first exposure dose. Third regions of the photoresist PR are not exposed. In some embodiments, the photoresist PR may be exposed by UV light, but the present disclosure is not limited in this regard. In some embodiments, the photoresist PR may be exposed by using a gray-tone mask (or a half-tone mask). For example, the half-tone mask may include full exposed portions where the full intensity of light (i.e., the first exposure dose) would be transmitted, half tone portions where parts of the light (e.g., the second exposure dose, which may be 20% to 60% of the first exposure dose) would be transmitted, and full tone portions where the light would be perfectly blocked.

During the intermediate stage of FIG. 5A, the photoresist PR is exposed and developed to be a patterned photoresist PR1 which include a first mask portion PR11 and a second mask portion PR12. The second mask portion PR12 is thicker than the first mask portion PR11. It can be seen that the regions of the photoresist PR exposed with the first exposure dose will be entirely removed, the regions of the photoresist PR exposed with the second exposure dose will be partially removed to form the first mask portion PR11, and the regions of the photoresist PR not exposed will be originally remained to form the second mask portion PR12.

Reference is made to FIG. 5B. FIG. 5B is a schematic cross-sectional view of an intermediate stage of a method of manufacturing an electrode structure according to some embodiments of the present disclosure. The intermediate stage shown in FIG. 5A may be sequentially followed by the intermediate stage shown in FIG. 5B. As shown in FIG. 5B, an etching process is performed to the first metal film L1 and the second metal film L2 through the patterned photoresist PR1 to form a bottom metal pattern BP.

Reference is made to FIG. 5C. FIG. 5C is a schematic cross-sectional view of an intermediate stage of a method of manufacturing an electrode structure according to some embodiments of the present disclosure. The intermediate stage shown in FIG. 5B may be sequentially followed by the intermediate stage shown in FIG. 5C. As shown in FIG. 50, the first mask portion PR11 is removed while the second mask portion PR12 is remained. In some embodiments, an ashing process is performed to the first mask portion PR11 and the second mask portion PR12 until the first mask portion PR11 is entirely removed and the second mask portion PR12 is still remained on the bottom metal pattern BP. In some embodiments, oxygen plasma is used in the ashing process to perform the erosion of the first mask portion PR11 and the second mask portion PR12. The remained second mask portion PR12 partially covers the top surface of the bottom metal pattern BP and serves a mask pattern of the bottom metal pattern BP in the subsequent anodizing step.

Reference is made to FIG. 5D. FIG. 5D is a schematic cross-sectional view of an intermediate stage of a method of manufacturing an electrode structure according to some embodiments of the present disclosure. The intermediate stage shown in FIG. 5C may be sequentially followed by the intermediate stage shown in FIG. 5D. As shown in FIG. 5D, the bottom metal pattern BP is anodized in a liquid electrolyte to form a covering anodized portion CA which covers an unanodized portion U. The covering anodized portion CA includes a sidewall oxide dielectric structure SD and a top oxide dielectric structure TD. The sidewall oxide dielectric structure SD is in contact with a side surface of the unanodized portion U. The top oxide dielectric structure TD is in contact with a part of a top surface of the unanodized portion U and a top surface of the sidewall oxide dielectric structure SD. The remained second mask portion PR12 covers the other part of the top surface of the unanodized portion U.

Reference is made to FIG. 5E. FIG. 5E is a schematic cross-sectional view of an intermediate stage of a method of manufacturing an electrode structure according to some embodiments of the present disclosure. The intermediate stage shown in FIG. 5D may be sequentially followed by the intermediate stage shown in FIG. 5E. As shown in FIG. 5E, the remained second mask portion PR12 is removed, such that the top surface of the unanodized portion U has a covered section A1 covered by the top oxide dielectric structure TD and an uncovered section A2 exposed by the top oxide dielectric structure TD.

Reference is made to FIG. 5F. FIG. 5F is a schematic top view of the structure in FIG. 5E according to some embodiments of the present disclosure. As shown in FIG. 5F, the top surface of the unanodized portion U has three uncovered sections A2 for example. Specifically, the right uncovered section A2 in FIG. 5F has a circular shape. The left uncovered section A2 in FIG. 5F has a rectangular shape. The middle uncovered section A2 in FIG. 5F extends across opposite edges of the top oxide dielectric structure TD. In practical applications, the shapes of the uncovered sections A2 can be flexibly modified as required.

In some embodiments, the bottom metal pattern BP is anodized to reach a termination voltage under 500 Volt. It should be pointed out that if the bottom metal pattern BP is anodized to reach a termination voltage greater than 500 Volt, the thickness of the covering anodized portion CA of the anodized bottom metal pattern BP′ may be too thick and result in high operation voltage of thin-film transistors to be manufactured.

In some embodiments, the bottom metal pattern BP is anodized at a temperature under 15° C. In this way, the covering anodized portion CA of the anodized bottom metal pattern BP′ will be denser and thus the quality can be improved.

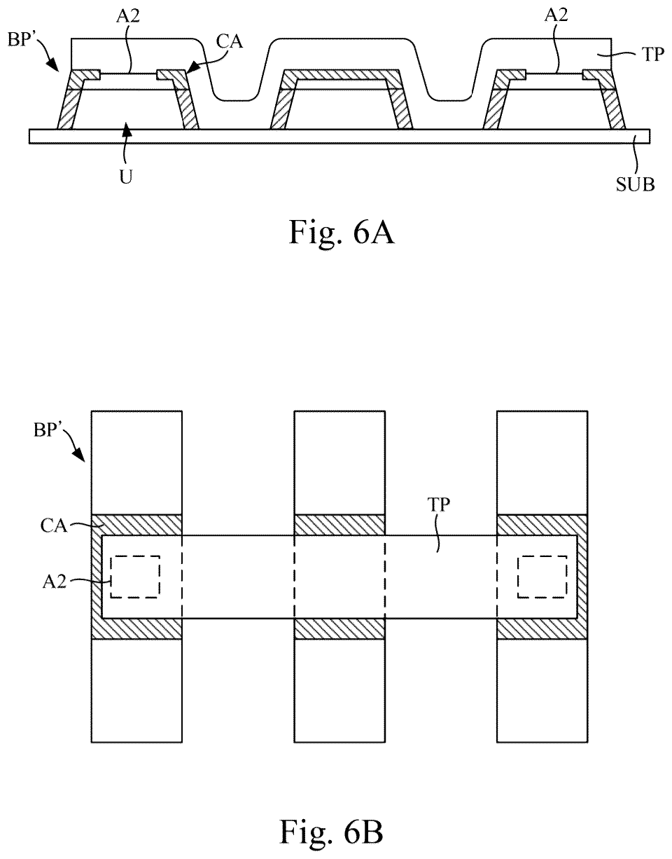

Reference is made to FIGS. 6A and 6B. FIG. 6A is a schematic cross-sectional view of a structure having multi-dielectric layers according to some embodiments of the present disclosure. FIG. 6B is a schematic top view of the structure of FIG. 6A according to some embodiments of the present disclosure. As shown in FIGS. 6A and 6B, the structure having multi-dielectric layers includes three anodized bottom metal patterns BP′ and a top conductive pattern TP. The top conductive pattern TP covers the covering anodized portions CA of the three anodized bottom metal patterns BP′. The top surfaces of the left and right anodized bottom metal patterns BP′ have uncovered sections A2 exposed and surrounded by the covering anodized portions CA, and the top conductive pattern TP is in contact with the unanodized portions U of the left and right anodized bottom metal patterns BP′ via the uncovered sections A2. In this way, the unanodized portions U of the left and right anodized bottom metal patterns BP′ are electrically connected to each other and form an interconnection structure with the top conductive pattern TP. The top conductive pattern TP crosses the unanodized portion U of the middle anodized bottom metal patterns BP′ through the covering anodized portions CA thereof. In this way, the top conductive pattern TP and the middle anodized bottom metal pattern BP′ form a cross over structure.

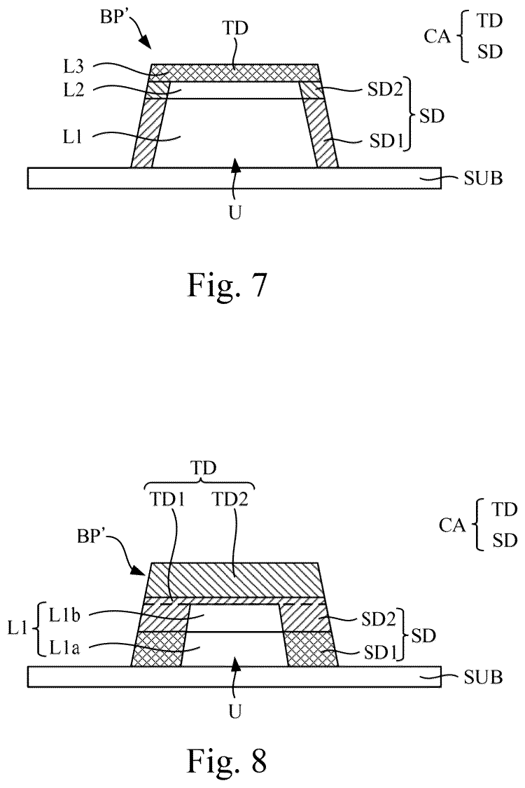

In some embodiments, at least one additional metal film may be deposited on the top surface of the second metal film L2 shown in FIG. 1A before the photoresist PR is formed. After sequentially performing the operations of the intermediate stages shown in FIGS. 1B to 1E, the structure shown in FIG. 7 can be obtained. As shown in FIG. 7, the additional metal film L3 on the top surface of the second metal film L2 is anodized. Although the additional metal film L3 shown in FIG. 7 is entirely anodized, but the present disclosure is not limited in this regard. In practical applications, the additional metal film L3 shown in FIG. 7 may be partially anodized.

In some embodiments, the additional metal film L3 contains silicon, but the present disclosure is not limited in this regard.

In some embodiments, the additional metal film L3 contains at least one of hafnium, tantalum, zirconium, titanium, and tungsten, but the present disclosure is not limited in this regard.

In some embodiments, the additional metal film L3 contains rare earth metal, but the present disclosure is not limited in this regard.

In some embodiments, the additional metal film L3 contains alkaline earth metal, but the present disclosure is not limited in this regard.

In some embodiments, the first metal film L1 is a multilayer structure. Reference is made to FIG. 8. FIG. 8 is a schematic cross-sectional view of a structure having multi-dielectric layers according to some embodiments of the present disclosure. As shown in FIG. 8, the first metal film L1 of the anodized bottom metal pattern BP′ includes a first metal layer L1a and a second metal layer L1b. To form the first metal film L1 as shown in FIG. 8, during the intermediate stage such as shown in FIG. 1A, the first metal layer L1a is deposited on the substrate SUB, and then the second metal layer L1b is deposited on the first metal layer L1a. Afterwards, the second metal film L2 is then deposited on the second metal layer L1b. As shown in FIG. 8, the sidewall oxide dielectric structure SD of the anodized bottom metal pattern BP′ includes a first metal oxide segment SD1 and a second metal oxide segment SD2 connected to each other. The first metal oxide segment SD1 is an anodized part of the first metal layer L1a, and the second metal oxide segment SD2 is an anodized part of the second metal layer L1b. The top oxide dielectric structure TD of the anodized bottom metal pattern BP′ includes a first metal oxide layer TD1 and a second metal oxide layer TD2 connected to each other. The first metal oxide layer TD1 is an anodized part of the second metal layer L1b, and the second metal oxide layer TD2 is an anodized part of the second metal film L2.

In some embodiments, a bottommost layer of the first metal film L1 (e.g., the first metal layer L1a) contains molybdenum or titanium. In this way, the first metal layer L1a containing molybdenum or titanium can enhance the adhesion of the first metal film L1 to the substrate SUB.

In some embodiments, the rest of the first metal film (e.g., the second metal layer L1b) has an atomic ratio of aluminum greater than 50%. In this way, the electrical conductivity of an entirety of the first metal film L1 can be increased.

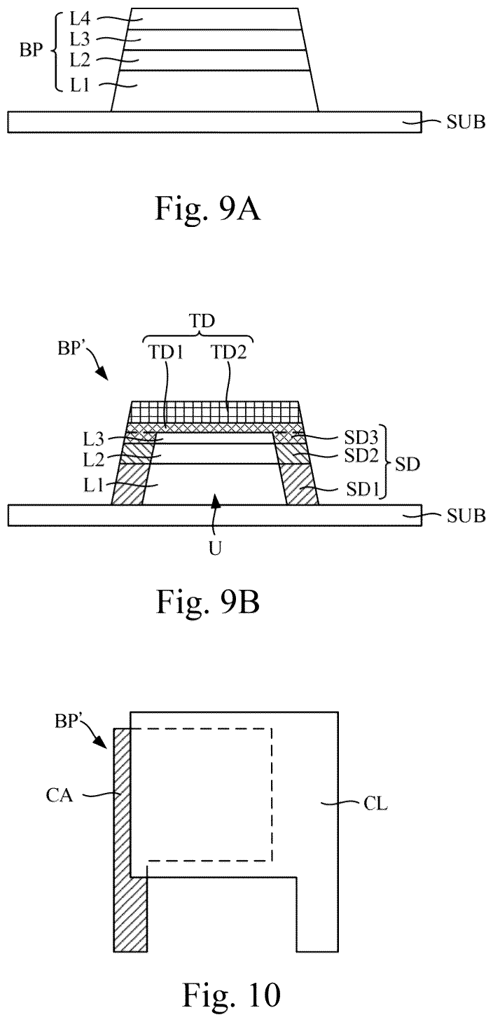

Reference is made to FIG. 9A. FIG. 9A is a schematic cross-sectional view of an intermediate stage of a method of manufacturing a structure having multi-dielectric layers according to some embodiments of the present disclosure. As shown in FIG. 9A, the bottom metal pattern BP includes a first metal layer L1, a second metal layer L2 deposited on the first metal layer L1, a third metal layer L3 deposited on the second metal layer L2, and a fourth metal layer L4 deposited on the third metal layer L3. The intermediate stage shown in FIG. 9A corresponds to the intermediate stage shown in FIG. 1D.

Reference is made to FIG. 9B. FIG. 9B is a schematic cross-sectional view of an intermediate stage of a method of manufacturing a structure having multi-dielectric layers according to some embodiments of the present disclosure. The intermediate stage shown in FIG. 9A may be sequentially followed by the intermediate stage shown in FIG. 9B, and the intermediate stage shown in FIG. 9B corresponds to the intermediate stage shown in FIG. 1E. As shown in FIG. 9B, an anodization process is performed to partially anodize the bottom metal pattern BP, such that the anodized bottom metal pattern BP′ includes an unanodized portion U, a sidewall oxide dielectric structure SD, and a top oxide dielectric structure TD. The sidewall oxide dielectric structure SD is in contact with a side surface of the unanodized portion U. The top oxide dielectric structure TD is in contact with a top surface of the unanodized portion U and a top surface of the sidewall oxide dielectric structure SD.

Specifically, the first metal layer L1, the second metal layer L2, and the third metal layer L3 are partially anodized, and the fourth metal layer L4 is entirely anodized. The sidewall oxide dielectric structure SD includes a first metal oxide segment SD1, a second metal oxide segment SD2, and a third metal oxide segment SD3 sequentially connected. The first metal oxide segment SD1 is the anodized part of the first metal layer L1, the second metal oxide segment SD2 is the anodized part of the second metal layer L2, and the third metal oxide segment SD3 is the anodized part of the third metal layer L3 below the top surface of the unanodized portion U. The first metal oxide segment SD1 is in contact with a side surface of the unanodized part of the first metal layer L1. The second metal oxide segment SD2 is in contact with a side surface of the unanodized part of the second metal layer L2. The third metal oxide segment SD3 is in contact with a side surface of the unanodized part of the third metal layer L3. In other words, the unanodized portion U is a multilayer structure formed by the unanodized part of the first metal layer L1, the unanodized part of the second metal layer L2, and the unanodized part of the third metal layer L3 below the top surface of the unanodized portion U. The top oxide dielectric structure TD includes a first metal oxide layer TD1 and a second metal oxide layer TD2 connected to each other. The first metal oxide layer TD1 is the anodized part of the third metal layer L3 above the top surface of the unanodized portion U, and the second metal oxide layer TD2 is the anodized fourth metal layer L4. The first metal oxide layer TD1 is in contact with a top surface of the unanodized part of the third metal layer L3. The second metal oxide layer TD2 is in contact with a top surface of the first metal oxide layer TD1. It can be seen that a sum of a segment number of the metal oxide segments of the sidewall oxide dielectric structure SD and a layer number of the metal oxide layer of the top oxide dielectric structure TD is equal to five.

Reference is made to FIG. 10. FIG. 10 is a schematic top view of a structure having multi-dielectric layers according to some embodiments of the present disclosure. As shown in FIG. 10, the structure having multi-dielectric layers further includes a conductor layer CL. The conductor layer CL covers the anodized bottom metal pattern BP′. Specifically, the conductor layer CL covers on the top oxide dielectric structure TD of the anodized bottom metal pattern BP′. In this way, the conductor layer CL forms a capacitor with the unanodized portion U in the anodized bottom metal pattern BP′ and under the top oxide dielectric structure TD. For example, a cross section of the combination of the conductor layer CL and the anodized bottom metal pattern BP′ may be similar to the cross section shown in FIG. 8. In some embodiments, the second effective permittivity of the top oxide dielectric structure TD is greater than the first effective permittivity of the sidewall oxide dielectric structure SD, such that the capacitance of this capacitor can be increased compared to a capacitor in which the first effective permittivity of the sidewall oxide dielectric structure SD is equal to the second effective permittivity of the top oxide dielectric structure TD.

In some embodiments, a thickness of the bottom metal pattern BP is less than 10 μm before the bottom metal pattern BP is anodized. It should be pointed out that if the thickness of the bottom metal pattern BP is greater than 10 μm, the deposition of the conductor layer CL will be more difficult to make good coverage.

In some embodiments, the combination of the conductor layer CL and the anodized bottom metal pattern BP′ shown in FIG. 10 may form a thin-film diode when the top oxide dielectric structure TD is thin enough. In general, the larger the voltage difference between the conductor layer CL and the unanodized portion U, the easier the current tunneling effect occurs.

Reference is made to FIG. 11. FIG. 11 is a schematic cross-sectional view of a structure having multi-dielectric layers according to some embodiments of the present disclosure. As shown in FIG. 11, in addition to the anodized bottom metal pattern BP′, the structure having multi-dielectric layers further includes a conductive pattern. The conductive pattern includes a bottom layer and a top layer. The bottom layer is an oxide semiconductor layer A, and the top layer is a metal layer including a source electrode SE and a drain electrode DE. The oxide semiconductor layer A covers the sidewall oxide dielectric structure SD and the top oxide dielectric structure TD of the anodized bottom metal pattern BP′. The source electrode SE covers the oxide semiconductor layer A. The drain electrode DE covers the oxide semiconductor layer A and is spaced apart from the source electrode SE by a gap G. The gap G is right above the unanodized portion U. In other words, the structure as shown in FIG. 11 is a thin-film transistor. The structure as shown in FIG. 11 may be manufactured by using a back-channel-etch (BCE) process, which will not be described in detail.

Reference is made to FIG. 12. FIG. 12 is a schematic cross-sectional view of a structure having multi-dielectric layers according to some embodiments of the present disclosure. As shown in FIG. 12, in addition to the anodized bottom metal pattern BP′, the structure having multi-dielectric layers further includes a conductive pattern and an etching stopper ES. The conductive pattern includes a bottom layer and a top layer. The bottom layer is an oxide semiconductor layer A, and the top layer is a metal layer including a source electrode SE and a drain electrode DE. The oxide semiconductor layer A covers the sidewall oxide dielectric structure SD and the top oxide dielectric structure TD of the anodized bottom metal pattern BP′. The etching stopper ES is disposed on the oxide semiconductor layer A and right above the unanodized portion U. The source electrode SE covers the oxide semiconductor layer A and the etching stopper ES. The drain electrode DE covers the oxide semiconductor layer A and the etching stopper ES and is spaced apart from the source electrode SE by a gap G on the etching stopper ES. In other words, the structure as shown in FIG. 12 is also a thin-film transistor. The structure as shown in FIG. 12 may be manufactured by using an etch-stop-layer (ESL) process, which will not be described in detail.

Reference is made to FIG. 13. FIG. 13 is a schematic cross-sectional view of a structure having multi-dielectric layers according to some embodiments of the present disclosure. As shown in FIG. 13, in addition to the anodized bottom metal pattern BP′, the structure having multi-dielectric layers further includes a conductive pattern. The conductive pattern includes a bottom layer and a top layer. The bottom layer is an oxide semiconductor layer A, and the top layer is a metal layer. The oxide semiconductor layer A covers the sidewall oxide dielectric structure SD and the top oxide dielectric structure TD of the anodized bottom metal pattern BP′. The metal layer includes an anodic oxide segment AO and two conductive segments electrically isolated from each other by the anodic oxide segment AO. The anodic oxide segment AO is right above the unanodized portion U. The two conductive segments of the metal layer respectively serve as a source electrode SE and a drain electrode DE. In other words, the structure as shown in FIG. 13 is also a thin-film transistor. The structure as shown in FIG. 13 may be manufactured by depositing the oxide semiconductor layer A to cover the anodized bottom metal pattern BP′, forming the metal layer to cover the oxide semiconductor layer A, and anodizing the metal layer to form the anodic oxide segment AO which reaches the oxide semiconductor layer A and separates the source electrode SE and the drain electrode DE. In some embodiments, the metal layer contains aluminum, such that the source electrode SE and the drain electrode DE also contain aluminum.

In some embodiments, the top oxide dielectric structure TD of the anodized bottom metal pattern BP′ includes an amorphous phase layer. For example, as shown in FIG. 2, the top oxide dielectric structure TD of the anodized bottom metal pattern BP′ is a multilayer structure, and the amorphous phase layer is a topmost layer (i.e., the second metal oxide layer TD2) of the top oxide dielectric structure TD. Since the amorphous phase layer has no grain boundary, the leakage current is relatively small. In some embodiments, aluminum contained in the top oxide dielectric structure TD keeps the second metal oxide layer TD2 amorphous.

In some embodiments, the second effective permittivity of the top oxide dielectric structure TD is greater than the first effective permittivity of the sidewall oxide dielectric structure SD, such that the threshold voltage of the thin-film transistors as shown in FIGS. 11-13 can be decreased.

According to the foregoing recitations of the embodiments of the disclosure, it can be seen that by performing the method of the present disclosure, a structure having an electrode (e.g., the unanodized portion of the anodized metal pattern) with multi-dielectric layers (e.g., the sidewall oxide dielectric structure and the top oxide dielectric structure) can be obtained. In some embodiments where the second effective permittivity of the top oxide dielectric structure is greater than the first effective permittivity of the sidewall oxide dielectric structure, the structure can have a large capacitance when it is applied to a capacitor, and the structure can have a small threshold voltage when it is applied to a thin-film transistor. In some embodiments where the second effective permittivity of the top oxide dielectric structure is smaller than the first effective permittivity of the sidewall oxide dielectric structure, the top oxide dielectric structure covering the unanodized portion can be stronger and more stable.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming an electrode with multi-dielectric layers, comprising:
forming a metal pattern on a substrate, wherein the metal pattern comprises a first metal film on the substrate and a second metal film on a top surface of the first metal film, and a metal composition of the first metal film and a metal composition of the second metal film are different; and
anodizing the metal pattern in a liquid electrolyte to form a covering anodized portion which covers an unanodized portion, wherein the covering anodized portion comprises a sidewall oxide dielectric structure and a top oxide dielectric structure, the sidewall oxide dielectric structure is in contact with a side surface of the unanodized portion, the top oxide dielectric structure is in contact with a top surface of the unanodized portion and a top surface of the sidewall oxide dielectric structure, and the sidewall oxide dielectric structure and the top oxide dielectric structure have different effective permittivities.

2. The method of claim 1, wherein the forming the metal pattern comprises:
depositing the first metal film on the substrate;
depositing the second metal film on the first metal film; and
performing an etching process to the first metal film and the second metal film to form the metal pattern, wherein the etching process is a photo engraving process.

3. The method of claim 1, wherein the first metal film is a multilayer structure.

4. The method of claim 3, wherein a bottommost layer of the first metal film contains molybdenum or titanium, and rest of the first metal film has an atomic ratio of aluminum greater than 50%.

5. The method of claim 1, wherein the second metal film contains aluminum.

6. The method of claim 5, wherein the second metal film is an aluminum alloy containing silicon.

7. The method of claim 5, wherein the second metal film is an alloy containing rare earth metal.

8. The method of claim 5, wherein the second metal film is an alloy containing alkaline earth metal.

9. The method of claim 1, wherein a material of the second metal film comprises at least one of hafnium, tantalum, zirconium, titanium, and tungsten.

10. The method of claim 1, further comprising:
forming a mask pattern on a portion of a top surface of the metal pattern before the anodizing; and
removing the mask pattern after the anodizing, such that the top surface of the unanodized portion has a covered section covered by the top oxide dielectric structure and at least one uncovered section exposed by the top oxide dielectric structure.

11. The method of claim 1, wherein the anodizing is performed to reach a termination voltage under 500 Volt.

12. The method of claim 1, wherein the anodizing is performed at a temperature under 15° C.

13. The method of claim 1, wherein the liquid electrolyte containing a content of water less than 20 wt %.

14. The method of claim 1, wherein the metal pattern further comprises at least one additional metal film on a top surface of the second metal film.

15. The method of claim 14, wherein the at least one additional metal film contains silicon.

16. The method of claim 14, wherein the at least one additional metal film contains at least one of hafnium, tantalum, zirconium, titanium, and tungsten.

17. The method of claim 14, wherein the at least one additional metal film contains rare earth metal.

18. The method of claim 14, wherein the at least one additional metal film contains alkaline earth metal.

19. The method of claim 1, further comprising:
forming a conductive pattern across the unanodized portion through the top oxide dielectric structure.

20. The method of claim 19, wherein the conductive pattern comprises a bottom layer and a top layer, the bottom layer is an oxide semiconductor layer, and the top layer is a metal layer.

21. The method of claim 1, wherein a thickness of the metal pattern is less than 10 μm before the anodizing.

22. The method of claim 1, wherein the second metal film is entirely anodized after the anodizing.

23. The method of claim 1, wherein the second metal film is partially anodized after the anodizing.

24. The method of claim 1, wherein the unanodized portion has an atomic ratio of aluminum greater than 50%.

25. The method of claim 1, wherein the effective permittivity of the top oxide dielectric structure is smaller than the effective permittivity of the sidewall oxide dielectric structure.

26. The method of claim 25, wherein the top oxide dielectric structure contains silicon oxide.

27. The method of claim 1, wherein the effective permittivity of the top oxide dielectric structure is greater than the effective permittivity of the sidewall oxide dielectric structure.
